(19) United States
(12) Patent Application Publication
(10) Pub. No.: US 2017/0029619 A1
(43) Pub. Date: Feb. 2, 2017

(54) THERMOSETTING RESIN COMPOSITION, AND RESIN VARNISH, METAL FOIL WITH RESIN, RESIN FILM, METAL-CLAD LAMINATE, AND PRINTED WIRING BOARD USING THE SAME

(71) Applicant: Panasonic Intellectual Property Management Co., Ltd., Osaka (JP)

(72) Inventors: LIN LIN, Osaka (JP); HIROAKI FUJIWARA, Nara (JP); YUKI KITAI, Osaka (JP)

(21) Appl. No.: 15/191,513

(22) Filed: Jun. 23, 2016

(30) Foreign Application Priority Data
Jul. 30, 2015 (JP) 2015-150733

(51) Int. Cl. C08L 71/12; H05K 1/03; C09D 109/06; H05K 1/02; C08L 9/06; C09D 171/12

(52) U.S. Cl. CPC C08L 71/126; C08L 9/06; C09D 171/12; C09D 109/06; H05K 1/0237; H05K 1/0373; C08L 2201/02; C08L 2203/20

(57) ABSTRACT

There is provided a thermosetting resin composition including: (A) a modified polyphenylene ether compound which is terminal-modified by using a substituent having a carbon-carbon unsaturated double bond at a molecular terminal; (B) a styrene-butadiene copolymer having a number average molecular weight less than 10,000 and including 1,2 vinyl having cross-linking properties in molecules; (C) a hardening accelerator; and (D) an inorganic filler, in which a compound ratio of (A) component:(B) component is in a range of 80:20 to 20:80.

### BACKGROUND OF THE INVENTION

1. Field of the Invention

The present disclosure relates to a thermosetting resin composition and a resin varnish, a metal foil with resin, a resin film, a metal-clad laminate, and a printed wiring board using the same.

2. Description of the Related Art

In recent years, capacity of signals of electrical apparatuses has been increased, and accordingly, dielectric characteristics such as a low dielectric constant or a low dielectric loss tangent necessary for high speed communication are required in a semiconductor substrate or the like.

It is known that polyphenylene ether (PPE) has excellent dielectric characteristics such as a dielectric constant or a dielectric loss tangent and excellent dielectric characteristics in a high frequency band (high frequency range) from MHz bands to GHz bands. Therefore, it is considered that polyphenylene ether is, for example, used as a molding material for high frequencies. More specifically, it is considered that polyphenylene ether is used as a substrate material or the like for configuring a base material of a printed wiring board included in an electrical apparatus using a high frequency zone.

A terminal-modified PPE resin is used as such a PPE resin (Japanese Patent Unexamined Publication No. 2015-86330), and a method of increasing a three-dimensional crosslinking density is used for maintaining heat-resisting properties in this terminal-modified PPE resin system.

Meanwhile, a prepreg obtained by impregnating a glass cloth with a hardening resin such as PPE has been widely used as a substrate material of a printed wiring board (for example, Japanese Patent Unexamined Publication No. 2014-1277).

However, in a substrate to which a high speed/high frequency signal in a bandwidth exceeding 10 Gbps flow, a glass cloth forming a substrate material (prepreg) has a higher dielectric constant, compared to that of a resin hardened product, and accordingly, a variation in dielectric constants (Dk) locally occurs in a substrate having parts where glass yarn is present and not present. Particularly, when a frequency is in a high frequency range, a single wavelength is measured in millimeters, and accordingly, a variation thereof becomes considerable and negative effects may be applied to applications in a high level.

In the related art, it has been reported that a period of transmission delay time of signals is shortened by narrowing a gap between glass fibers using a glass cloth-opening substrate and preventing a variation in dielectric constants in a substrate surface, but a period of transmission delay time of signals between differential circuit wires cannot be completely eliminated. Therefore, in the disclosure, it is considered to use a metal foil with resin (for example, a copper foil with resin (RCC)) obtained by applying a resin varnish onto a surface of a metal foil or a resin film as a substrate material, without using a glass cloth.

### SUMMARY OF THE INVENTION

In a polyphenylene ether resin composition disclosed in Japanese Patent Unexamined Publication No. 2015-86330, it is possible to provide a laminate having dielectric characteristics and heat-resisting properties.

A method of increasing a three-dimensional crosslinking density for applying heat-resisting properties is often used for a PPE resin which is terminal-modified by using a substituent having a carbon-carbon unsaturated double bond. However, it is found that as a three-dimensional crosslinking density increases, thermosetting shrinkage of a resin increases, and a molded one-side metal-clad laminate is significantly curled, when using a metal foil with resin without using a glass cloth.

An object of the disclosure is to provide a thermosetting resin composition capable of preventing a variation in in-plane dielectric constants while retaining excellent dielectric characteristics of a hardened product of a resin composition and preventing curling (warping) of a substrate material. In addition, another object of the disclosure is to provide a metal foil with resin and a resin film using the thermosetting resin composition, a metal-clad laminate obtained by using the metal foil with resin and the resin film, and a printed wiring board manufactured by using the metal foil with resin and the resin film.

According to an aspect of the disclosure, there is provided a thermosetting resin composition including: (A) a modified polyphenylene ether compound which is terminal-modified by using a substituent having a carbon-carbon unsaturated double bond at a molecular terminal; (B) a styrene-butadiene copolymer having a number average molecular weight less than 10,000 and including 1,2 vinyl having cross-linking properties in molecules; (C) a hardening accelerator; and (D) an inorganic filler, in which a compound ratio of (A) component:(B) component is in a range of 80:20 to 20:80.

In the thermosetting resin composition, it is preferable that a styrene content in (B) styrene-butadiene copolymer is from 20 mass % to 50 mass % and a butadiene content is from 50 mass % to 80 mass %.

In the thermosetting resin composition, it is preferable that a 1,2 vinyl content in butadiene of (B) styrene-butadiene copolymer is from 30% to 70%.

In the thermosetting resin composition, it is preferable that a weight average molecular weight of (A) modified polyphenylene ether compound is equal to or greater than 1,000 and (A) modified polyphenylene ether compound has an intrinsic viscosity of 0.03 dl/g to 0.12 dl/g which is obtained by measuring the intrinsic viscosity in chloroform at 25° C.

In the thermosetting resin composition, it is preferable that a substituent of a terminal of (A) modified polyphenylene ether compound is a substituent including at least one kind selected from a group consisting of a vinyl benzyl group, an acrylate group, and a methacrylate group.

In the thermosetting resin composition, it is preferable that (C) hardening accelerator contains at least one kind selected from a group consisting of an organic peroxide, an azo compound, and a dihalogen compound. In the thermosetting resin composition, it is preferable that an equivalent ratio of (C) hardening accelerator with respect to (A) modified polyphenylene ether compound is from 0.1 to 2.

It is preferable that the thermosetting resin composition further includes (E) a flame retardant.

According to another aspect of the disclosure, there is provided a resin varnish including: the thermosetting resin composition; and a solvent.

In the resin varnish, it is preferable that the solvent is at least one kind selected from a group consisting of toluene, cyclohexane, and propylene glycol monomethyl ether acetate.

According to still another aspect of the disclosure, there is provided a metal foil with resin including: a resin layer formed of the thermosetting resin composition; and a metal foil.

According to still another aspect of the disclosure, there is provided a resin film including: a resin layer formed of the thermosetting resin composition; and a film supporting base material.

According to still another aspect of the disclosure, there is provided a metal-clad laminate including: at least one sheet of the metal foil with resin and the resin film; and a metal foil provided on both upper and lower surfaces or one surface of the sheet.

According to still another aspect of the disclosure, there is provided a printed wiring board including: a resin layer formed of the thermosetting resin composition, and a conductor pattern provided on a surface of the resin layer as a circuit.

According to the disclosure, it is possible to provide a thermosetting resin composition having excellent dielectric characteristics and heat-resisting properties in a hardened product thereof and excellent film forming properties, and in which a variation in dielectric constants in a substrate (a metal foil with resin) to be obtained and warpage of a substrate are prevented, and a resin varnish, a resin film, a metal foil with resin, a metal-clad laminate and a printed wiring board using the same.

### DETAILED DESCRIPTION OF THE PREFERRED EMBODIMENTS

A thermosetting resin composition according to an embodiment of the disclosure includes: (A) a modified polyphenylene ether compound which is terminal-modified by using a substituent having a carbon-carbon unsaturated double bond at a molecular terminal; (B) a styrene-butadiene copolymer having a number average molecular weight less than 10,000 and including 1,2 vinyl having cross-linking properties in molecules; (C) a hardening accelerator; and (D) an inorganic filler, in which a compound ratio of (A) component:(B) component is in a range of 80:20 to 20:80.

The thermosetting resin composition has excellent dielectric characteristics, heat-resisting properties, and film forming properties, and can prevent a variation in dielectric constants in a substrate surface of a metal foil with resin to be obtained and occurrence of warpage. It is thought that a difference in a transmission rate between differential signals in an electronic substrate to be obtained can be reduced by preventing a variation in dielectric constants. This is particularly significantly advantageous for realizing an increase in a data transmission rate of so-called differential transmission.

Hereinafter, each component of the thermosetting resin composition according to the embodiment will be described in detail.

Modified polyphenylene ether used in the embodiment is not particularly limited, as long as it is modified polyphenylene ether which is terminal-modified by using a substituent having a carbon-carbon unsaturated double bond.

The substituent having a carbon-carbon unsaturated double bond is not particularly limited, and a substituent represented by the following Formula 1 is used, for example.

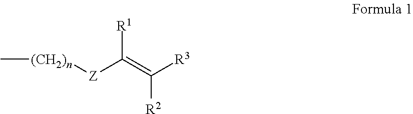

(in the formula, n represents an integer of 0 to 10, Z represents an arylene group, and R¹ to R³ each independently represent a hydrogen atom or an alkyl group.)

Herein, in a case where n is 0 in Formula 1, Z represents a group directly bonded to a terminal of polyphenylene ether. Examples of an arylene group as Z include a monocyclic aromatic group such as a phenylene group or a polycyclic aromatic group such as naphthalene rings, and also include a derivative obtained by substituting a hydrogen atom bonded to an aromatic ring with a functional group such as an alkenyl group, an alkynyl group, a formyl group, an alkylcarbonyl group, an alkenylcarbonyl group, or an alkynylcarbonyl group.

As a preferred specific example of a functional group represented by Formula 1, a functional group containing a vinylbenzyl group is used, and specifically, at least one substituent selected from the following Formula 2 or Formula 3 is used, for example.

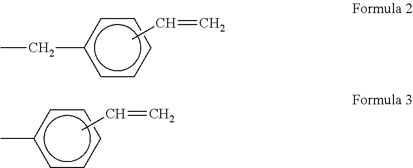

An acrylate group or a methacrylate group is used as other substituents to be terminal-modified in modified polyphenylene ether used in the embodiment and having a carbon-carbon unsaturated double bond, and an example thereof is shown in the following Formula 4.

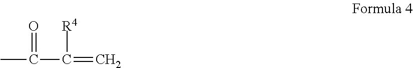

(in the formula, R⁴ represents a hydrogen atom or an alkyl group.)

A weight average molecular weight of the (A) modified polyphenylene ether used in the embodiment is not particularly limited and is preferably equal to or greater than 1,000. The weight average molecular weight thereof is preferably from 1,000 to 7,000, more preferably from 1,000 to 5,000, and even more preferably from 1,000 to 3,000. Herein, the weight average molecular weight may be measured by a general molecular weight measuring method, and specifically, a value measured using gel permeation chromatography (GPC) or the like is used.

It is considered that a resin composition having excellent dielectric characteristics of polyphenylene ether and a high Tg and excellent adhesiveness and heat-resisting properties in a hardened product thereof in a good balance is more reliably obtained, when the weight average molecular weight of the modified polyphenylene ether is in the range described above.

In the modified polyphenylene ether used in the embodiment, an average number (number of terminal substituents) of substituents having a carbon-carbon unsaturated double bond at a molecular terminal, per one molecule of modified polyphenylene ether is preferably from 1.5 to 3, more preferably from 1.7 to 2.7, and even more preferably from 1.8 to 2.5. When the number of substituents is excessively small, a crosslinking point may be difficult to form and sufficient heat-resisting properties of a hardened product may not be obtained. When the number of terminal substituents is excessively large, problems such as a decrease in preserving properties of the polyphenylene ether resin composition or a decrease in fluidity of the polyphenylene ether resin composition may occur, for example, due to excessively high reactivity.

The number of terminal substituents of the modified polyphenylene ether is a numerical value representing an average value of the numbers of substituents per one molecule of all modified polyphenylene ether present in one mole of modified polyphenylene ether. The number of terminal substituents, for example, can be measured by measuring the number of hydroxyl groups remaining in the obtained modified polyphenylene ether and calculating the amount decreased from the number of hydroxyl groups of polyphenylene ether before modification. The amount decreased from the number of hydroxyl groups of polyphenylene ether before modification indicates the number of terminal functional groups. The number of hydroxyl groups remaining in the modified polyphenylene ether can be obtained by adding quaternary ammonium salts (tetraethyl ammonium hydroxide) associating with a hydroxyl group to a solution of modified polyphenylene ether and measuring UV absorbance of the mixed solution.

An intrinsic viscosity of the modified polyphenylene ether used in the embodiment is preferably from 0.03 dl/g to 0.12 dl/g, more preferably from 0.04 dl/g to 0.11 dl/g, and even more preferably from 0.06 dl/g to 0.095 dl/g. When the intrinsic viscosity is excessively low, a molecular weight tends to be decreased and low dielectric characteristics such as a low dielectric constant or a low dielectric loss tangent tend to be hardly obtained. When the intrinsic viscosity is excessively high, a viscosity may be increased, sufficient fluidity may not be obtained, and molding properties of a hardened product tends to be decreased. Accordingly, as long as the intrinsic viscosity of the modified polyphenylene ether is in the range described above, it is possible to realize excellent heat-resisting properties and adhesiveness of a hardened product.

The intrinsic viscosity herein is an intrinsic viscosity obtained by measuring the intrinsic viscosity in methylene chloride at 25° C. and is, more specifically, a value obtained by measuring the intrinsic viscosity of a methylene chloride solution (liquid temperature of 25° C.) having a content of 0.18 g/45 ml using a viscometer. AVS500 Visco System manufactured by Schott is used, for example, as a viscometer.

In the modified polyphenylene ether used in the embodiment, it is desirable that a content of a component having a high molecular weight in which a molecular weight is equal to or greater than 13,000 is equal to or less than 5 mass %. That is, it is preferable that molecular weight distribution of the modified polyphenylene ether of the embodiment is comparatively narrow. In particular, in the modified polyphenylene ether of the embodiment, the content of a component having a high molecular weight in which a molecular weight is equal to or greater than 13,000 is preferably small. Such a component having a high molecular weight may not be contained and a lower limit value in a content range of a component having a high molecular weight in which a molecular weight is equal to or greater than 13,000 may be 0 mass %. The content of a component having a high molecular weight in which a molecular weight in the modified polyphenylene ether is equal to or greater than 13,000 may be from 0 mass % to 5 mass % and more preferably from 0 mass % to 3 mass %. As described above, when modified polyphenylene ether having a small content of a component having a high molecular weight and narrow molecular weight distribution is used, a polyphenylene ether resin composition having higher reactivity contributing to a hardening reaction and more excellent fluidity may be obtained.

The content of such a component having a high molecular weight can be, for example, calculated based on molecular weight distribution measured using gel permeation chromatography (GPC). Specifically, the content thereof can be calculated from a percentage of a peak area based on a curve showing molecular weight distribution measured using GPC.

In the modified polyphenylene ether according to the embodiment, it is preferable that a polyphenylene ether chain is in the molecule thereof and a repeating unit represented by the following Formula 5 is in a molecule, for example.

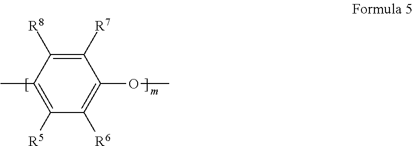

In Formula 5, m represents an integer of 1 to 50. R⁵, R⁶, R⁷, and R⁸ are independent of each other. That is, R⁵, R⁶, R⁷, and R⁸ each may be the same group or different groups. In addition, R⁵, R⁶, R⁷, and R⁸ represent a hydrogen atom, an alkyl group, an alkenyl group, an alkynyl group, a formyl group, an alkylcarbonyl group, an alkenylcarbonyl group, or an alkynylcarbonyl group. Among these, R⁵, R⁶, R⁷, and R⁸ preferably represent a hydrogen atom and an alkyl group.

Specifically, in R⁵, R⁶, R⁷, and R⁸, the following groups are used as each functional group described above.

An alkyl group is not particularly limited and an alkyl group having 1 to 18 carbon atoms is preferable and an alkyl group having 1 to 10 carbon atoms is more preferable, for example. Specifically, examples thereof include a methyl group, an ethyl group, a propyl group, a hexyl group, and a decyl group.

An alkenyl group is not particularly limited and an alkenyl group having 2 to 18 carbon atoms is preferable and an alkenyl group having 2 to 10 carbon atoms is more preferable, for example. Specifically, examples thereof include a vinyl group, an allyl group, and a 3-butenyl group.

An alkynyl group is not particularly limited and an alkynyl group having 2 to 18 carbon atoms is preferable and an alkynyl group having 2 to 10 carbon atoms is more preferable, for example. Specifically, examples thereof include an ethynyl group and a prop-2-yn-1-yl group (propargyl group).

An alkylcarbonyl group is not particularly limited as long as it is a carbonyl group substituted with an alkyl group, and an alkylcarbonyl group having 2 to 18 carbon atoms is preferable and an alkylcarbonyl group having 2 to 10 carbon atoms is more preferable, for example. Specifically, examples thereof include an acetyl group, a propionyl group, a butyryl group, an isobutyryl group, a pivaloyl group, a hexanoyl group, an octanoyl group, and a cyclohexylcarbonyl group.

An alkenylcarbonyl group is not particularly limited as long as it is a carbonyl group substituted with an alkenyl group, and an alkenylcarbonyl group having 3 to 18 carbon atoms is preferable and an alkenylcarbonyl group having 3 to 10 carbon atoms is more preferable, for example. Specifically, examples thereof include an acryloyl group, a methacryloyl group, and a crotonoyl group.

An alkynylcarbonyl group is not particularly limited as long as it is a carbonyl group substituted with an alkynyl group, and an alkynylcarbonyl group having 3 to 18 carbon atoms is preferable and an alkynylcarbonyl group having 3 to 10 carbon atoms is more preferable, for example. Specifically, examples thereof include a propioloyl group and the like.

In a case where the modified polyphenylene ether includes a repeating unit represented by Formula 5 in molecules thereof, m is preferably a numerical value so that the weight average molecular weight of the modified polyphenylene ether is in the range described above. Specifically, m is preferably an integer of 1 to 50.

A synthesis method of the (A) modified polyphenylene ether used in the embodiment is not particularly limited, as long as modified polyphenylene ether which is terminal-modified by using a substituent having a carbon-carbon unsaturated double bond can be synthesized. Specifically, a method of causing a reaction between polyphenylene ether in which hydrogen atoms of a phenolic hydroxyl group at a terminal are substituted with alkali metal atoms such as sodium or potassium, and a compound represented by the following Formula 6 is used, for example.

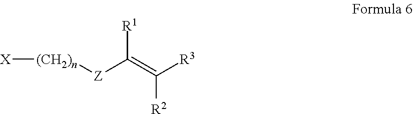

In Formula 6, n represents an integer of 0 to 10, Z represents an arylene group, and R¹ to R³ each independently represent a hydrogen atom or an alkyl group, in the same manner as in Formula 1. In addition, X represents a halogen atom and specific examples thereof include a chlorine atom, a bromine atom, an iodine atom, a fluorine atom. Among these, a chlorine atom is preferable.

The compound represented by Formula 6 is not particularly limited, and p-chloromethylstyrene or m-chloromethylstyrene is preferable, for example.

The compound represented by Formula 6 may be used alone as elements described above or may be used in combination of two or more kinds thereof.

Polyphenylene ether which is a raw material is not particularly limited, as long as predetermined modified polyphenylene ether can be finally synthesized. Specific examples thereof include elements having polyphenylene ether as a main component such as a polyarylene ether copolymer formed of 2,6-dimethyl phenol and at least one of bifunctional phenol and trifunctional phenol, and poly (2,6-dimethyl-1,4-phenylene oxide). More specifically, polyphenylene ether having a structure represented by Formula 7 is used as such polyphenylene ether.

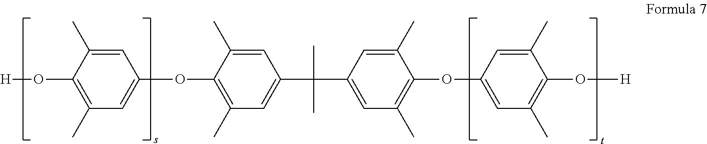

In Formula 7, a total value of s and t is, for example, preferably 1 to 30. In addition, s is preferably from 0 to 20 and t is preferably from 0 to 20. That is, it is preferable that s represents a value of 0 to 20, t represents a value of 0 to 20, and the total of s and t represents a value of 1 to 30.

The method described above is used as a synthesizing method of the modified polyphenylene ether, and specifically, polyphenylene ether described above and the compound represented by Formula 6 are dissolved and stirred in a solvent. By doing so, polyphenylene ether reacts with the compound represented by Formula 6 and the modified polyphenylene ether used in the embodiment is obtained.

At the time of this reaction, it is preferable that the reaction is performed under the presence of alkali metal hydroxides. By doing so, it is thought that this reaction suitably proceeds.

The alkali metal hydroxides are not particularly limited as long as alkali metal hydroxides serve as a dehalogenating agent, and sodium hydroxides are used, for example. The alkali metal hydroxides are normally used in a state of an aqueous solution and are specifically used as a sodium hydroxide aqueous solution.

The reaction conditions such as a period of reaction time and a reaction temperature vary depending on the compound represented by Formula 6 and are not particularly limited, as long as the reaction conditions are conditions in which the reaction described above suitably proceeds. Specifically, a reaction temperature is preferably in a range of room temperature to 100° C. and more preferably from 30° C. to 130° C. In addition, a period of reaction time is preferably from 0.5 hours to 20 hours and more preferably from 0.5 hours to 10 hours.

A solvent used at the time of a reaction is not particularly limited, as long as a solvent can dissolve polyphenylene ether and the compound represented by Formula 6 and a solvent does not disturb a reaction between polyphenylene ether and the compound represented by Formula 6. Specifically, examples thereof include toluene and the like.

In addition, it is preferable that the reaction described above is performed under the presence of a phase transfer catalyst, not only alkali metal hydroxides. That is, it is preferable that the reaction described above is performed under the presence of alkali metal hydroxides and a phase transfer catalyst. By doing so, it is thought that the reaction described above more suitably proceeds.

The phase transfer catalyst is not particularly limited and quaternary ammonium salts such as tetra-n-butyl ammonium bromide is used, for example.

The polyphenylene ether resin composition according to the embodiment preferably contains the modified polyphenylene ether obtained as described above, as the modified polyphenylene ether.

Then, the (B) component used in the embodiment, that is, a styrene-butadiene copolymer having a number average molecular weight less than 10,000 and including 1,2 vinyl having cross-linking properties in molecules will be described.

A styrene-butadiene copolymer including 1,2 vinyl having cross-linking properties in molecules is, for example, a copolymer having a structure represented by the following Formula 8.

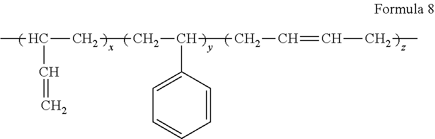

Formula (8) shows an example of a styrene-butadiene copolymer which can be used in the embodiment, and x represents a 1,2 vinyl group, y represents a styrene group, and z represents a 2,3 vinyl group, respectively.

By causing 1,2 vinyl having high cross-linking properties to be included in molecules as described above, the styrene-butadiene copolymer of the embodiment has reactivity, compared to a typical styrene-butadiene copolymer having a large amount of 2,3 vinyl groups.

Since a molecular weight thereof is low as a number average molecular weight less than 10,000, 1,2 vinyl group in the styrene-butadiene copolymer has higher reactivity contributing to a hardening reaction. The molecular weight thereof is not particularly limited as long as the number average molecular weight thereof is less than 10,000, and is preferably equal to or greater than 2,000 from viewpoints of film forming properties, fluidity, compatibility, and tackiness. The number average molecular weight is more preferably from 3,000 to 9,000.

In the embodiment, the number average molecular weight of the styrene-butadiene copolymer can be measured by gel permeation chromatography (GPC), for example.

In the styrene-butadiene copolymer of the embodiment, a styrene content in molecules thereof is preferably from 20 mass % to 80 mass % and a butadiene content is preferably from 50 mass % to 80 mass %. That is, relationships among x, y, and z shown in Formula (8) preferably satisfy an expression of 20%≦y/(x+y+z)≦50% and an expression of 50%≦(x+z)/(x+y+z)≦80%, respectively. By doing so, excellent compatibility between the (A) component and the (B) component is obtained and a period of hardening time of a resin component can be shortened. In addition, it is thought that excellent heat-resisting properties can be applied to a resin composition.

In the embodiment, styrene and butadiene contents in the styrene-butadiene copolymer can be measured by nuclear magnetic resonance spectrometry (NMR), for example.

In the styrene-butadiene copolymer of the embodiment, a 1,2 vinyl content in butadiene is preferably from 30% to 70%. That is, a relationship between x and z shown in Formula (8) preferably satisfies an expression of 30%≦x/(x+z)≦70%. By doing so, it is thought that a resin composition having a high Tg and excellent adhesiveness and heat-resisting properties in a hardened product thereof in a good balance can be obtained.

In the embodiment, the content of a 1,2 vinyl group in butadiene of the styrene-butadiene copolymer can be measured by infrared absorption spectrometry (Morello method), for example.

A compound ratio between the (A) component and the (B) component of the embodiment is in a range of 80:20 to 20:80. It is thought that desired heat-resisting properties, flexibility, low dielectric constant, and low dielectric loss tangent can be obtained by setting such a compound ratio described above. The compound ratio between the (A) component and the (B) component is more preferably in a range of 70:30 to 30:70, and when the compound ratio is in the range described above, excellent compatibility between the (A) component and the (B) component is obtained and a period of hardening time of a resin component can be shortened. The compound ratio is even more preferably in a range of 60:40 to 40:60, and when the compound ratio is in the range described above, more excellent film flexibility and film forming properties are obtained and occurrence of warpage can be more reliably prevented, in addition to the effects described above.

In the embodiment, the “compound ratio” described above indicates a compound ratio when mixing components when preparing a resin composition or a component ratio thereof in a varnish state.

The (B) styrene-butadiene copolymer of the embodiment can be synthesized by copolymerizing a styrene monomer and a 1,3 butadiene monomer, for example. Alternatively, a commercially available product can be used, and “Ricon 181”, “Ricon 100” or “Ricon 184” manufactured by Cray Valley is used as a specific example thereof.

Next, the (C) hardening accelerator will be described. The hardening accelerator used in the embodiment is not particularly limited as long as it promotes hardening of the thermosetting compound described above.

Preferably, a hardening accelerator is used so that an equivalent ratio thereof with respect to the (A) modified polyphenylene ether compound which is a thermosetting compound is from 0.1 to 2.

As a preferred specific example of the hardening accelerator of the embodiment, at least one kind selected from an organic peroxide, an azo compound, and a dihalogen compound is used, for example. In addition, the hardening accelerator may be used alone or in combination of two or more kinds thereof.

The thermosetting resin composition of the embodiment further contains the (D) inorganic filler.

An inorganic filler which can be used in the embodiment is not particularly limited and examples thereof include spherical silica, barium sulfate, silicon oxide powder, crushed silica, calcined talc, barium titanate, titanium oxide, clay, alumina, mica, boehmite, zinc borate, zinc stannate, and other metal oxides or metal hydrates. When such an inorganic filler is contained in the resin composition, it is possible to prevent thermal expansion of a laminate or the like and to increase dimensional stability.

It is preferable to use silica to obtain advantages of improving heat-resisting properties or dielectric loss tangent (Df) of a laminate.

It is preferable that a content of the (D) component in the resin composition is in a range of 10 parts by mass and 400 parts by mass, with respect to 100 parts by mass of the total of the (A), (B), and (C) components. When the content of the inorganic filler is less than 10 parts by mass, a coefficient of thermal expansion and dimensional stability of a substrate may be deteriorated and when the content thereof exceeds 400 parts by weight, resin fluidity may be deteriorated.

The thermosetting resin composition of the embodiment may further contain the (E) flame retardant. By doing so, it is possible to further increase flame retardance of a hardened product of the polyphenylene ether resin composition.

Examples of a flame retardant which can be used in the embodiment include a phosphorus-based flame retardant, a halogen-based flame retardant, and the like. Examples thereof include phosphinic acid salt-based flame retardants such as phosphoric acid ester such as condensed phosphoric acid ester and a cyclic phosphoric acid ester; a phosphazene compound such as a cyclic phosphazene compound; and phosphinic acid metal salts such as dialkylphosphinic acid aluminum salts. Examples of a halogen-based flame retardant include a bromine-based flame retardant and the like. The flame retardant may be used alone as each flame retardant described above or in combination of two or more kinds thereof.

In a case where the polyphenylene ether resin composition of the embodiment contains a flame retardant, a content thereof is preferably from 0 part by weight to 30 parts by weight with respect to total 100 parts by weight of (A)+(B)+(C). The content of the flame retardant is preferably a content so that a content of phosphorus atoms in the resin composition is in the range described above. When such a content is set, a resin composition having more excellent flame retardance of a hardened product is obtained while retaining excellent dielectric characteristics of the polyphenylene ether compound.

The thermosetting resin composition according to the embodiment may be formed of the (A) to (D) components, and when these compulsory components are contained, other components may be contained in a range not inhibiting operation effects of the disclosure. As other components, a resin modifier, an antioxidant, and the like are used, for example.

The thermosetting resin composition of the embodiment may further contain a resin component such as an epoxy resin, for example, but the resin component of the resin composition of the embodiment is preferably formed of only a thermosetting resin. As described above, since thermoplastic components are not contained, a resin composition having excellent chemical resistance, heat-resisting properties, and dimensional stability may be obtained.

The thermosetting resin composition according to the embodiment is used as a resin varnish by preparing the thermosetting resin composition in a varnish state, in many cases, when manufacturing a metal foil with resin such as RCC and the like. Such a resin varnish is, for example, prepared as described below.

First, components which can be dissolved in an organic solvent such as the (A) modified polyphenylene ether compound, the (B) styrene-butadiene copolymer, the (C) hardening accelerator, and compatible flame retardants are put into an organic solvent and dissolved therein. At this time, the components may be heated, if necessary. Then, components which are not dissolved in the organic solvent such as the (D) inorganic filler and, if necessary, incompatible flame retardants are added thereto and dispersed using a ball mill, a bead mill, a planetary mill, and a roll mill until the resultant material is in a predetermined dispersed state, to prepare a varnish-like resin composition. The organic solvent used herein is not particularly limited, as long as it dissolves the (A) modified polyphenylene ether compound, the (B) styrene-butadiene copolymer, the (C) hardening accelerator, and flame retardants and does not inhibit a hardening reaction. Specific examples thereof include toluene, cyclohexanone, and propylene glycol monomethyl ether acetate. These may be used alone or in combination of two or more kinds thereof.

A resin varnish of the embodiment has an advantage of excellent film flexibility and film forming properties and easy handling.

A metal foil with resin of the embodiment has a configuration in which a resin layer formed of the resin composition described above and a metal foil are laminated on each other. As a method of manufacturing such a metal foil with resin, a method of applying the resin varnish obtained as described above onto a surface of a metal foil such as a copper foil and drying the resin varnish is used, for example.

A resin film of the embodiment has a configuration in which a resin layer formed of the resin composition described above and a film supporting base material are laminated on each other. As a method of manufacturing such a resin film, a method of applying the resin varnish obtained as described above onto a surface of a film supporting base material such as a PET film and drying the resin varnish to harden or partially harden the resin varnish.

A thickness and the like of the metal foil or the film supporting base material can be suitably set according to a desired purpose. For example, as a copper foil, a foil having a thickness of approximately 12 μm to 70 μm can be used. The application of the resin varnish onto a metal foil or a film supporting base material is performed by coating or the like, and this operation can be repeated multiple times, if necessary. At this time, the coating is repeated using a plurality of resin varnishes having different compositions and concentrations and a composition (content ratio) and a resin amount can be finally adjusted to desired composition and resin amount.

After coating the resin varnish, heating is performed under the desired heating conditions, for example, at 80° C. to 170° C. for 1 minute to 10 minutes to remove a solvent, and accordingly, a metal foil with resin or a resin film in a half-hardened state (B stage) is obtained. The metal foil with resin or the resin film obtained by using the resin composition of the embodiment has good quality in which warpage is prevented, a variation in dielectric constants in plane is prevented, and handling is also excellent, in addition to excellent dielectric characteristics and heat-resisting properties.

A metal-clad laminate of the embodiment includes at least one sheet of the metal foil with resin and the resin film, and a metal foil provided on both upper and lower surfaces or one surface of the sheet.

In a method of manufacturing a metal-clad laminate using the metal foil with resin or the resin film obtained as described above, a double-sided metal foil-clad or a single-sided metal foil-clad laminate can be manufactured by laminating one sheet or a plurality of sheets of a metal foil with resin or a resin film on each other, and further laminating a metal foil such as a copper foil on both upper and lower surfaces or one surface of the sheet described above, and heating, pressurizing, and molding the laminated material to integrate the laminate. The heating and pressurizing conditions can be suitably set by a thickness of a laminate to be manufactured or a kind of a resin composition, and a temperature can be set to be from 170° C. to 220° C., pressure can be set to be from 1.5 MPa to 5.0 MPa, and time can be set to be from 60 minutes to 150 minutes, for example.

A printed wiring board of the embodiment includes a resin layer formed of the thermosetting resin composition described above and a conductor pattern provided on a surface of the resin layer as a circuit. As a manufacturing method of such a printed wiring board, a printed wiring board in which a conductor pattern is provided on a surface of a laminate as a circuit can be obtained by forming a metal foil on a surface of the manufactured laminate as a circuit by etching processing. The printed wiring board obtained by using the resin composition of the embodiment has excellent dielectric characteristics, is easy to be mounted and has no variation in quality, even when the printed wiring board is set in a package state by bonding a semiconductor chip thereto, and has excellent signal rate or impedance.

This specification discloses technologies of various aspects described above, but the main technology thereof is described below.

According to an aspect of the disclosure, there is provided a polyphenylene ether resin composition including: (A) a modified polyphenylene ether compound which is terminal-modified by using a substituent having a carbon-carbon unsaturated double bond at a molecular terminal; (B) a styrene-butadiene copolymer having a number average molecular weight less than 10,000 and including 1,2 vinyl having cross-linking properties in molecules; (C) a hardening accelerator; and (D) an inorganic filler, in which a compound ratio of (A) component:(B) component is in a range of 80:20 to 20:80.

By setting such a configuration, it is possible to provide a thermosetting resin composition having excellent dielectric characteristics and heat-resisting properties in a hardened product thereof and excellent film forming properties, and in which a variation in dielectric constants in a substrate (a metal foil with resin) to be obtained and warpage of a substrate are prevented. It is thought that a difference in a transmission rate between signals of differential transmission in an electronic substrate to be obtained can be reduced by preventing a variation in dielectric constants.

In the thermosetting resin composition, it is preferable that a styrene content in the (B) styrene-butadiene copolymer is from 20 mass % to 50 mass % and a butadiene content is from 50 mass % to 80 mass %.

Accordingly, in addition to the effects described above, excellent heat-resisting properties and excellent compatibility of resin components are obtained and a period of hardening time can be reduced.

A 1,2 vinyl content in butadiene of the (B) styrene-butadiene copolymer is preferably from 30% to 70%. Accordingly, it is possible to further improve heat-resisting properties and adhesiveness.

In the thermosetting resin composition, it is preferable that a weight average molecular weight of the (A) modified polyphenylene ether compound is equal to or greater than 1,000 and the (A) modified polyphenylene ether compound has an intrinsic viscosity of 0.03 dl/g to 0.12 dl/g which is obtained by measuring the intrinsic viscosity in chloroform at 25° C. Accordingly, the above-mentioned effects can be more reliably obtained and more excellent heat-resisting properties and adhesiveness of a hardened material can be realized.

In the thermosetting resin composition, it is preferable that the substituent at a terminal of the (A) modified polyphenylene ether compound is a substituent including at least one kind selected from a group consisting of a vinyl benzyl group, an acrylate group, and a methacrylate group. Accordingly, it is thought that the above-mentioned effects can be more reliably obtained.

In the thermosetting resin composition, it is preferable that the (C) hardening accelerator contains at least one kind selected from a group consisting of an organic peroxide, an azo compound, and a dihalogen compound. In the thermosetting resin composition, it is preferable that an equivalent ratio of the (C) hardening accelerator with respect to the (A) modified polyphenylene ether compound is from 0.1 to 2. Accordingly, it is possible to further improve heat-resisting properties and adhesiveness of a hardened material.

It is preferable that the thermosetting resin composition further includes (E) a flame retardant. Accordingly, it is possible to obtain a resin composition having higher flame retardance.

According to another aspect of the disclosure, there is provided a resin varnish including: the thermosetting resin composition; and a solvent.

In the resin varnish, it is preferable that the solvent is at least one kind selected from a group consisting of toluene, cyclohexane, and propylene glycol monomethyl ether acetate.

According to still another aspect of the disclosure, there is provided a metal foil with resin including: a resin layer formed of the thermosetting resin composition; and a metal foil.

According to still another aspect of the disclosure, there is provided a resin film including: a resin layer formed of the thermosetting resin composition; and a film supporting base material.

According to still another aspect of the disclosure, there is provided a metal-clad laminate including: at least one sheet of the metal foil with resin and the resin film; and a metal foil provided on both upper and lower surfaces or one surface of the sheet.

According to still another aspect of the disclosure, there is provided a printed wiring board including: a resin layer formed of the thermosetting resin composition, and a conductor pattern provided on a surface of the resin layer as a circuit.

According to such configurations, since warpage of the metal foil with resin of the disclosure is prevented and a variation in dielectric constants in plane is also prevented, it is possible to provide a metal-clad laminate and a printed wiring board which are easy to be mounted and have no variation in quality, and have excellent signal rate or impedance, when preparing a printed wiring board. It is thought that a difference in a transmission rate between signals of differential circuits in an electronic substrate to be obtained can be reduced by preventing a variation in dielectric constants. This is particularly significantly advantageous for realizing an increase in a data transmission rate of so-called differential transmission.

Hereinafter, the disclosure will be described more specifically using examples but a scope of the disclosure is not limited thereto.

### EXAMPLES

First, modified polyphenylene ether was synthesized. An average number of phenolic hydroxyl groups at a molecular terminal per one molecule of polyphenylene ether is shown as a terminal hydroxyl group number.

### [Synthesis of Modified Polyphenylene Ether 1 (Modified PPE 1)]

Modified polyphenylene ether 1 (modified PPE 1) was obtained by causing a reaction between polyphenylene ether and chloromethylstyrene. Specifically, first, 200 g of polyphenylene ether (polyphenylene ether having a structure shown in Formula (5), SA90 manufactured by SABIC Innovative Plastics Corporation, an intrinsic viscosity (IV) of 0.083 dl/g, terminal hydroxyl group number of 1.9, a weight molecular weight Mw of 1,700), 30 g of a mixture in which a mass ratio of p-chloromethylstyrene and m-chloromethylstyrene is 50:50 (chloromethylstyrene: CMS manufactured by Tokyo Chemical Industry Co., Ltd.), 1.227 g of tetra-n-butyl ammonium bromide as a phase transfer catalyst, and 400 g of toluene were put and stirred in a 1-liter three-neck flask including a temperature controller, a stirring device, a cooling device, and a drop-type funnel. Polyphenylene ether, chloromethylstyrene, and tetra-n-butyl ammonium bromide were stirred until those are dissolved in toluene. At this time, heating is slowly performed until a solution temperature finally becomes 75° C. A sodium hydroxide aqueous solution (20 g of sodium hydroxide/20 g of water) is added to the solution dropwise as alkali metal hydroxides for 20 minutes. Then, stirring was performed at 75° C. for 4 hours. Next, the content in a flask is neutralized by 10 mass % of hydrochloric acid and mass of methanol was put therein. By doing so, precipitate was generated in liquid in a flask. That is, a product contained in reaction liquid in a flask was reprecipitated. This precipitate was extracted by filtering, the resultant material was washed three times using a mixed solution in which a mass ratio between methanol and water is 80:20, and dried at 80° C. for 3 hours under the reduced pressure.

The obtained solid was analyzed using 1H-NMR (400 MHz, CDCl₃, TMS). As a result of measuring NMR, a peak derived from ethenyl benzyl was confirmed as 5 ppm to 7 ppm. Accordingly, it was confirmed that the obtained solid is modified polyphenyl ether having a group represented by Formula (1) at a molecular terminal. Specifically, polyphenylene ether which is converted into ethenyl benzyl was confirmed.

The molecular weight distribution of the modified polyphenylene ether was measured using GPC. As a result of calculating the weight average molecular weight (Mw) from the obtained molecular weight distribution, Mw was 1,900.

The terminal functional number of the modified polyphenylene ether was measured as follows.

First, the modified polyphenylene ether was accurately weighed. The weight at this time was set as X (mg). The weighed modified polyphenylene ether was dissolved in 25 ml of methylene chloride, 100 μl of an ethanol solution (TEAH:ethanol (volume ratio)=15:85) of 10 mass % of tetraethyl ammonium hydroxide (TEAH) was added to the solution thereof, and absorbance (Abs) at 318 nm was measured using a UV spectrophotometer (UV-1600 manufactured by Shimadzu Corporation). From the measured results, the terminal hydroxyl group number of modified polyphenylene ether was calculated using the following equation.

Remaining OH amount (μmol/g)=[(25×Abs)/(∈×OPL×X)]×106

Herein, ∈ represents an absorbance index and is 4700 L/mol·cm. The OPL is a cell path length and is 1 cm.

Since the calculated remaining OH amount (terminal hydroxyl group number) of the modified polyphenyl ether is substantially zero, a hydroxyl group of polyphenylene ether before modification was substantially modified. Therefore, it was found that the amount decreased from the number of terminal hydroxyl groups of polyphenylene ether before modification is the terminal hydroxyl group number of polyphenylene ether before modification. That is, it was found that the terminal hydroxyl group number of polyphenylene ether before modification is the number of terminal functional groups of modified polyphenylene ether. That is, the terminal functional number was 1.8.

Then, a styrene-butadiene copolymer (SBR) was synthesized.

### [Synthesis of SBR 1]

A SBR 1 (styrene: 15 mass %, butadiene: 85 mass %, 1,2 vinyl in butadiene: 30 mass %, number average molecular weight of 6,000) was manufactured as follows.

700 parts of a 1,3-butadiene monomer, 70 parts of a styrene monomer, 10 parts of tetrahydrofuran, and 2 millimoles of t-butoxypotassium were put into 1000 parts of cyclohexane dehydrated under the nitrogen atmosphere and a temperature in a vessel was set to 50° C. Then, 5 millimoles of n-butyl lithium were added and polymerization was performed at an increased temperature. After the number average molecular weight reached 8000 while performing GPC monitoring of a polymerization conversion ratio in a polymerization reaction, a coupling reaction was performed by adding 0.75 millimoles of tin tetrachloride. Then, 2.5 g of 2,6-di-t-butyl-p-cresol was added to a polymer solution and drying for removing a solvent was performed. The generation of a styrene-butadiene copolymer obtained was confirmed by NMR.

### [Synthesis of SBR 2]

A SBR 2 (styrene: 55 mass %, butathene: 45 mass %, 1,2 vinyl in butathene: 30 mass %, number average molecular weight of 8,000) was manufactured as follows.

The synthesis of SBR 2 was performed in the same manner as in Synthesis Example 1, except for changing blending amounts to 300 parts of a styrene monomer and 480 parts of a 1,3-butathene monomer.

### [Synthesis of SBR 3]

A SBR 3 (styrene: 28 mass %, butathene: 72 mass %, 1,2 vinyl in butathene: 30 mass %, number average molecular weight of 15,000) was manufactured as follows.

The synthesis of SBR 3 was performed in the same manner as in Synthesis Example 1, except for changing blending amounts to 200 parts of a styrene monomer and 520 parts of a 1,3-butathene monomer.

### Examples 1 to 9 and Comparative Examples 1 to 3

Components used when preparing a thermosetting resin composition in the examples will be described.

### (A Component: Polyphenylene Ether)

Modified PPE 1: modified polyphenylene ether obtained by the synthesis method described above

### (B Component: Styrene-Butadiene Copolymer)

Styrene-butadiene copolymer (“Ricon 181 (product name)” manufactured by Cray Valley, styrene: 28 mass %, butadiene: 72 mass %, 1,2 vinyl in butathene: 30%, number average molecular weight of 3200)
Styrene-butadiene copolymer (SBR 1): SBR 1 obtained by the synthesis method described above
Styrene-butadiene copolymer (SBR 2): SBR 2 obtained by the synthesis method described above
Styrene-butadiene copolymer (SBR 3): SBR 3 obtained by the synthesis method described above

The number average molecular weight of the styrene-butadiene copolymer was measured by gel permeation chromatography (GPC), the styrene butadiene content was measured by NMR, and the content of 1,2 vinyl group in butadiene was measured by infrared absorption spectrometry (Morello method).

### (C Component: Hardening Accelerator)

Peroxide: “Perbutyl P” (manufactured by NOF Corporation)

### (D Component: Inorganic Filler)

spherical silica “SC2300-SVJ” (manufactured by Admatechs)

### (E Component: Flame Retardant)

SAYTEX 8010 (manufactured by Albemarle Japan Corporation)

### [Preparation Method]

### (Resin Varnish)

First, the (A) modified polyphenylene ether compound and toluene were mixed with each other, a mixed solution was heated to 80° C., the (A) was dissolved in toluene, and a toluene solution having 65 mass % of (A) was obtained. Then, the (B) styrene-butadiene copolymer and the (C) hardening accelerator were added to a toluene solution of the obtained (A) so as to have rates shown in Table 1, and stirred for 30 minutes to be completely dissolved. The (D) inorganic filler and the (E) flame retardant were further added and dispersed using a bead mill to obtain a varnish-like resin composition (resin varnish).

(Copper Foil with Resin)

A copper foil with resin (RCC) was prepared using the varnish and is used in the evaluation which will be described later.

A copper foil having a thickness of 18 μm (“FV-WS” manufactured by Furukawa Electric Co., Ltd.) was used in the RCC. The resin varnish was applied to the surface of the copper foil so that a thickness after hardening becomes 50 μm and heated and dried at 130° C. for 3 minutes until the resin varnish is in a semi-hardened state, to obtain the RCC.

### (Metal-Clad Laminate)

A copper-clad laminate (CCL) having a thickness of 100 μm (evaluation substrate) in which two sheets of the RCC are bonded to each other, and heated and pressurized under the vacuum conditions at a temperature of 200° C., pressure of 30 kg/cm² for 120 minutes to bond the copper foil to both surfaces, was obtained.

### <Evaluation Test>

Each resin varnish and evaluation laminate prepared as described above were evaluated by a method shown below.

### [RCC Warpage Prevention (Single-Sided Plate)]

Two sheets of the RCC are bonded to each other and prepreg molding is performed at 200° C. Then, a copper foil on one surface was completely etched and the CCL in a state where copper foil is bonded to one surface is used. The CCL was put on a surface plate so that a recessed surface of the CCL becomes a lower surface, a distance between the surface plate and a surface of a product on a recessed surface side was set as H, a distance of H was measured, and H was set as determination criteria of warpage.

Evaluation Criteria:
EX: H≦5 mm
GD: 5 mm<H≦20 mm
NG: H>20 mm
(EX: Excellent, GD: Good, NG: No Good)

### [Film Flexibility•Film Forming Properties]

An insulating resin side of a coated insulating adhesive film was folded at 180° to form a crease and then unfolded, and a generation state of cracks of a film around the crease was visually observed.

Evaluation Criteria:
EX: No cracks
GD: Slight cracks are generated but the resin around the crease was not cracked
OK: Apparent cracks were generated, but the resin was not cracked
(EX: Excellent, GD: Good, OK: Okay)

### [Glass Transition Temperature (Tg)]

The Tg of the copper-clad laminate obtained as described above was measured using a visco-elastic spectrometer “DMS 100” manufactured by Seiko Instruments Inc. At this time, dynamic viscoelasticity measurement (DMA) was performed by setting a frequency as 10 Hz using a tensile module, and a temperature at which maximum tan δ when increasing a temperature from room temperature to 320° C. under the conditions of a rate of temperature rise of 5° C./min is obtained, was set as Tg.

### [Dielectric Characteristics (Dielectric Constants (Dk) and Dielectric Loss Tangent (Df))]

The dielectric constants and the dielectric loss tangent of the evaluation substrate (copper-clad laminate described above) at 10 GHz were measured by a resonance cavity perturbation method. Specifically, the dielectric constants and the dielectric loss tangent of the evaluation substrate at 1 GHz and 10 GHz were measured by using a network analyzer (N5230A manufactured by Agilent Technologies).

### [Soldering Heat Resistance]

The soldering heat resistance after absorption was measured by the following method. First, the obtained copper-clad laminate having a size of 50 mm×50 mm was etched, a pressure cooker test (PCT) at 121° C., 2 atmospheric pressure (0.2 MPa), for 6 hours was performed using each sample, five samples were clip in a soldering pot at 288° C. or 260° C. for 20 seconds, and occurrence of measling or blistering was visually observed.

Evaluation Criteria:
EX: No blistering and measling occur at 288° C.
GD: No blistering and measling occur at 260° C. and at least one of blistering and measling at 288° C. occurs
NG: At least one of blistering and measling at 260° C. occurs
(EX: excellent, GD: Good, NG: No Good)

### [Oven Heat Resistance Test at 280° C.]

When a test piece manufactured based on JIS C 6481 was processed in a thermostat attached to an air circulator set at 280° C. for 1 hour using a copper-clad laminate obtained, a level in which no “blistering” and “peeling” occur in 10 sheets of the test piece was determined as “Ex (Excellent)”, a level in which the number of sheets where “blistering” and “peeling” occur in 10 sheets of the test piece is within three sheets was determined as “GD (Good)”, and a level in which “blistering” and “peeling” occur in four or more samples in 10 sheets of the test piece was determined as “NG (No Good)”.

### [Period of Hardening Time (Step Time)]

When the gelation of varnish proceeds by rotating a rotor by a gelation tester and a constant torque is applied, the rotor is dropped by a magnetic coupling mechanism, and a heating time until a timer stops is set as a period of hardening time. This period of hardening time was evaluated as criteria.

Evaluation Criteria:
EX: period of hardening time<5 min
GD: 5 min<period of hardening time<30 min
OK: 30 min<period of hardening time<80 min
(EX: Excellent, GD: Good, OK: Okay)

### [Resin Compatibility (Blending Time)]

The resin (A) and the resin (B) were mixed with each other at a ratio of 90:10 to 10:90 and stirred for 30 minutes, and precipitation, opacity, and a layer separated state of the mixed resin were observed. A small amount was extracted from the mixed resin to apply on a case glass, and transparency of a film was confirmed. The cast film was dried at 130° C. for 3 minutes and the transparency of the film was visually observed.

Evaluation Criteria:
EX: in confirmation after stirring, no precipitation, opacity, and layer separation were observed
GD: the stirred resin is slightly opaque, but the cast film is transparent
OK: the cast film is opaque, but the film after drying at 130° C. for 3 minutes becomes transparent
NG: two components are not mixed with each other in all states
(EX: Excellent, GD: Good, NG: No Good)

The test results described above are shown in Table 1.

TABLE 1

| compo- | | Example 1 | Example 2 | Example 3 | Example 4 | Example 5 | Example 6 |
|---|---|---|---|---|---|---|---|
| nent | material name | blending | blending | blending | blending | blending | blending |
| (A) | terminal modified PPE | 80 | 70 | 60 | 50 | 40 | 30 |
| (B) | SBR(commercially available) | 20 | 30 | 40 | 50 | 60 | 70 |
| | SBR1 | | | | | | |
| | SBR2 | | | | | | |
| | SBR3 | | | | | | |

| | | |
|---|---|---|
| (C) | peroxide | 2 |
| (D) | spherical silica | 250 |
| (E) | SAYTEX8010 | 19 |

| | | Example 1 | Example 2 | Example 3 | Example 4 | Example 5 | Example 6 |
|---|---|---|---|---|---|---|---|
| | item | performance | performance | performance | performance | performance | performance |
| evalua- | RCC warp prevention | GD | GD | EX | EX | EX | GD |
| tion | (single-sided plate) | | | | | | |
| test | film flexilibity and film | GD | GD | EX | EX | EX | GD |
| | forming properties | | | | | | |
| | Tg(DMA) | 230 | 220 | 220 | 210 | 200 | 190 |
| | dielectric constants | 3.0 | 3.0 | 3.0 | 2.8 | 2.8 | 2.8 |
| | (@10 GHz) | | | | | | |
| | dielectric loss tangent | 0.003 | 0.002 | 0.002 | 0.002 | 0.002 | 0.002 |
| | (@10 GHz) | | | | | | |
| | Soldering Heat Resistance | GD | GD | EX | EX | GD | GD |
| | Oven Heat Resistance | GD | GD | EX | EX | GD | GD |
| | 280° C. | | | | | | |
| | Period of hardening time | EX | EX | EX | EX | GD | OK |
| | (step time) | | | | | | |
| | Resin compatibility | EX | EX | EX | EX | GD | OK |
| | (visually observed at | | | | | | |
| | the time of blending) | | | | | | |

| compo- | | Example 7 | Example 8 | Example 9 | Comparative | Comparative | Comparative |
|---|---|---|---|---|---|---|---|
| nent | material name | blending | blending | blending | Example 1 | Example 2 | Example 3 |
| (A) | terminal modified PPE | 20 | 70 | 70 | 70 | 60 | 50 |
| (B) | SBR(commercially available) | 80 | | | | | |
| | SBR1 | | 30 | | | | |
| | SBR2 | | | 30 | | | |
| | SBR3 | | | | 30 | 40 | 50 |

| | | |
|---|---|---|
| (C) | peroxide | 2 |
| (D) | spherical silica | 250 |
| (E) | SAYTEX8010 | 19 |

| | | | | | Comparative | Comparative | Comparative |
|---|---|---|---|---|---|---|---|
| | | Example 7 | Example 8 | Example 9 | Example 1 | Example 2 | Example 3 |
| | item | performance | performance | performance | performance | performance | performance |
| evalua- | RCC warp prevention | GD | GD | GD | NG | NG | NG |
| tion | (single-sided plate) | | | | | | |
| test | film flexilibity and film | GD | GD | GD | OK | GD | GD |
| | forming properties | | | | | | |
| | Tg(DMA) | 190 | 210 | 200 | 180 | 180 | 180 |
| | dielectric constants | 2.8 | 3.0 | 3.0 | 3.0 | 2.8 | 2.8 |
| | (@10 GHz) | | | | | | |
| | dielectric loss tangent | 0.002 | 0.003 | 0.003 | 0.002 | 0.002 | 0.002 |
| | (@10 GHz) | | | | | | |
| | Soldering Heat Resistance | GD | GD | GD | NG | NG | NG |
| | Oven Heat Resistance | GD | GD | GD | NG | NG | NG |
| | 280° C. | | | | | | |
| | Period of hardening time | OK | GD | GD | GD | OK | OK |
| | (step time) | | | | | | |
| | Resin compatibility | OK | NG | EX | NG | NG | NG |
| | (visually observed at | | | | | | |
| | the time of blending) | | | | | | |

(EX: Excellent, GD: Good, OK: Okay, NG: No Good)

From the above description, it was found that it is possible to provide a resin composition having excellent dielectric characteristics and heat-resisting properties and excellent film forming properties, and in which warpage of a substrate material to be obtained can be prevented, by the disclosure. In addition, since a fiber base material such as a glass cloth is not used in a metal foil with resin of this example, a variation in dielectric constants in plane is prevented.

With respect to this, in a comparative example having small molecular weight of the (B) content, warpage of a hardened material is not prevented and heat-resisting properties were deteriorated.

From results of Examples 6 and 7, it was found that excellent resin compatibility is obtained and a period of hardening time can be shortened, when a compound ratio between the (A) component and the (B) component is in a suitable range. It was found that significantly excellent film flexibility was obtained and occurrence of warpage can be further prevented by setting a suitable compound ratio (see Examples 3 to 5).

From the results of Example 9, it was found that heat-resisting properties can be controlled by adjusting the styrene•butadiene content in the (B) component.

What is claimed is:

1. A thermosetting resin composition comprising:
(A) a modified polyphenylene ether compound which is terminal-modified by using a substituent having a carbon-carbon unsaturated double bond at a molecular terminal;
(B) a styrene-butadiene copolymer having a number average molecular weight less than 10,000 and including 1,2 vinyl having cross-linking properties in molecules;
(C) a hardening accelerator; and
(D) an inorganic filler,
wherein a compound ratio of (A) component:(B) component is in a range of 80:20 to 20:80.

2. The thermosetting resin composition of claim 1,
wherein in (B) styrene-butadiene copolymer, a styrene content is from 20 mass % to 50 mass % and a butadiene content is from 50 mass % to 80 mass %.

3. The thermosetting resin composition of claim 1,
wherein a 1,2 vinyl content in butadiene of (B) styrene-butadiene copolymer is from 30% to 70%.

4. The thermosetting resin composition of claim 1,
wherein a weight average molecular weight of (A) modified polyphenylene ether compound is equal to or greater than 1,000 and (A) modified polyphenylene ether compound has an intrinsic viscosity of at least 0.03 dl/g and at most 0.12 dl/g which is obtained by measuring the intrinsic viscosity in chloroform at 25° C.

5. The thermosetting resin composition of claim 1,
wherein the substituent of a terminal of (A) modified polyphenylene ether compound is a substituent including at least one kind selected from a group consisting of a vinyl benzyl group, an acrylate group, and a methacrylate group.

6. The thermosetting resin composition of claim 1,
wherein (C) hardening accelerator contains at least one kind selected from a group consisting of an organic peroxide, an azo compound, and a dihalogen compound.

7. The thermosetting resin composition of claim 1,
wherein an equivalent ratio of (C) hardening accelerator with respect to (A) modified polyphenylene ether compound ranges from 0.1 to 2, inclusive.

8. The thermosetting resin composition of claim 1, further comprising:
(E) a flame retardant.

9. A resin varnish comprising:
the thermosetting resin composition of claim 1; and
a solvent.

10. The resin varnish of claim 9,
wherein the solvent is at least one kind selected from a group consisting of toluene, cyclohexane, and propylene glycol monomethyl ether acetate.

11. A metal foil with resin, comprising:
a resin layer formed of the thermosetting resin composition of claim 1; and
a metal foil.

12. A resin film comprising:
a resin layer formed of the thermosetting resin composition of claim 1; and
a film supporting base material.

13. A metal-clad laminate comprising:
at least one sheet of the metal foil with resin of claim 11; and
a metal foil provided on both upper and lower surfaces of the sheet or on one of the upper and lower surfaces of the sheet.

14. A printed wiring board comprising:
a resin layer formed of the thermosetting resin composition of claim 1; and
a conductor pattern provided on a surface of the resin layer as a circuit.
